(19) United States
(12) Patent Application Publication
(10) Pub. No.: US 2007/0066778 A1
(43) Pub. Date: Mar. 22, 2007

(54) Pn-semiconductor inorganic/organic hybrid material, its method of production and photovoltaic cell comprising said material

(76) Inventors: Philippe Belleville, Tours (FR); Clement Sanchez, Yuelte (FR); Pierrick Buvat, Dontrazon (FR); Philippe Prene, Tours (FR)

Correspondence Address: MCKENNA LONG & ALDRIDGE LLP, 1900 K STREET, NW, WASHINGTON, DC, 20006, US

(21) Appl. No.: 10/579,226

(22) PCT Filed: Nov. 16, 2004
(86) PCT No.: PCT/FR04/50591

§ 371 Date: May 12, 2006

(30) Foreign Application Priority Data
Nov. 17, 2003 (FR) 03 50841

(51) Int. Cl. C08F 30/04

(52) U.S. Cl. 526/240; 526/241

(57) ABSTRACT

The invention relates to a pn-semiconductor material that can be obtained by a method comprising in succession the following steps: a step in which a substrate made of a porous oxide ceramic is functionalized by chemical grafting of one or more compounds containing at least one group that can be polymerized with one or more precursors of an electrically conducting polymer and at least one group able to be chemically grafted onto said substrate; a step in which said substrate thus functionalized is impregnated with a solution containing said precursor(s); and a step in which said precursor or precursors are polymerized. Application of these materials to photovoltaic cells.

### TECHNICAL FIELD

The present invention relates to a pn-semiconductor inorganic/organic hybrid material intended to be used in the construction of a photoelectrochemical cell, more particularly a photovoltaic cell.

The present invention also relates to a method of producing such a material and to a photovoltaic cell comprising said material.

The general field of the invention is therefore that of photoelectrochemical cells, more particularly photovoltaic cells, or else light-emitting diodes.

### PRIOR ART

A photovoltaic cell is a device for converting photochemical energy into electrical energy.

In general, a photovoltaic cell is made up of p-doped semiconductor materials (that is to say those having a deficiency of electrons, i.e. holes) and of n-doped semiconductor materials (that is to say those having an excess of electrons) joined together to form a junction called a “pn junction”, which provides separation between the electrons and the holes. This separation generates a potential difference at the pn junction and consequently an electric current if a contact is placed on the n-region and a contact on the p-region and a resistor (namely a device intended to be supplied with electric current) between these two contacts.

Thus, when light strikes that region of the cell consisting of the junction between the p-type semiconductor material and the n-type semiconductor material, the constituent photons of the light are absorbed by said region and each absorbed photon creates an electron and a hole (referred to as an electron-hole pair), said pair being separated at the junction between the n-type material and the p-type material, thus creating a potential difference on either side of this junction.

Until recently, most photovoltaic cells have been produced from silicon, more precisely silicon doped with atoms such as phosphorus in order to form the n-region and silicon doped with atoms such as boron in order to form the p-region of the cell. However, it turns out to be costly to use silicon.

To remedy this drawback, research has been focussed on developing new materials that can be used to construct photovoltaic cells.

Thus, photovoltaic cells have been designed from a pn-type semiconductor material comprising a solid n-semiconductor region and a liquid p-semiconductor region. More precisely, the n-semiconductor region consists of a porous oxide ceramic, for example titanium dioxide, the pores of which are filled with a charge-conducting liquid electrolyte, this electrolyte fulfilling the role of p-semiconductor region.

This type of photovoltaic cell is described for example in International Patent Application WO 93/19479 [1].

However, it has been found that photovoltaic cells using a liquid electrolyte have the following drawbacks:

low stability over time, owing to the evaporation of the solvents used in the composition of the electrolyte;

relatively limited operating temperature range because of the volatile nature of the solvents used in the formation of the electrolyte;

risk of precipitating the salts used in forming the electrolyte, when the photovoltaic cell is made to operate at very low temperatures, such as temperatures of around −10° C. to −40° C.; and

constricting implementation owing to the use of a liquid electrolyte, excluding in particular the use of flexible organic supports and/or those of large dimensions.

To remedy this, research work has focussed on designing photovoltaic cells comprising pn-semiconductor materials, comprising both a solid n-semiconductor region and a solid p-semiconductor region.

Thus, Patent Application EP 1 176 646 [2] discloses photovoltaic cells comprising an n-semiconductor region consisting of a titanium oxide ceramic sensitized with inorganic semiconductor nanoparticles and comprising a p-semiconductor region formed by a hole-conducting organic molecule belonging to the family of Spiro and heterospiro compounds, in particular the polymer 2,2′,7,7′-tetrakis(N,N-di-p-methoxyphenylamine)9,9′-spirobifluorene (known by the abbreviation OMeTAD). This p-region is obtained by spin-coating the n-region using a solution comprising OMeTAD and chlorobenzene. However, the contact time during which the OMeTAD-containing solution is in contact with the titanium oxide layer is relatively short owing to the rapid evaporation of chlorobenzene and to the deposition method used. This results in particular in limited interpenetration of the n- and p-regions, this limited interpenetration also being due to the slow diffusion of the OMeTAD molecules towards the internal surfaces of the ceramic (namely the pore wall surfaces). This limited interpenetration of the n- and p-regions results in a very low solar efficiency.

In addition, the interaction between the n-region consisting of an oxide ceramic and the p-region formed by the abovementioned charge-conducting polymer is a weak interaction, owing to the fact that the conducting polymer is bound to the ceramic by adsorption, more particularly via weak interactions of the van der Waals type.

Patent Application EP 0 917 208 [3] discloses a photovoltaic cell comprising a photoactive film consisting of an organic polymer matrix based on polyparaphenylenevinylene (known by the abbreviation PPV) in which semiconductor-type nanoparticles (particularly TiO₂) are dispersed. In this configuration, the PPV provides the hole conduction function (i.e. the function of a p-semiconductor region) and the function of a chromophore, by absorbing the photons from the light, whereas the dispersed nanoparticles provide the electron conduction role (n-semiconductor region). However, this type of configuration has the following drawbacks:

the dispersion of nanoparticles in the organic matrix limits the percolation of the nanoparticles and thus limits the conduction of electrons to the electron-collecting layer of the photovoltaic cell; and

the dispersion of nanoparticles in the organic matrix results in a high rate of electron-hole recombination at PPV/nanoparticle interfaces.

Patent Application WO 93/20569 [4] discloses a dye-based photovoltaic cell comprising a region formed by a porous titanium oxide film sensitized with a chromophore and a region consisting of a hole-conducting polymer. The method of producing this type of photovoltaic cell consists in depositing, at high temperature (around 300° C.), the conducting polymer in the molten state onto the porous titanium oxide film. However, the material obtained has the following drawbacks:

it is characterized by interpenetration between the porous film and the polymer that is limited by the diffusion of the polymer in the molten state into the porosity of the titanium oxide film;

it comprises a loose junction between the n-semiconductor material and the p-semiconductor material due to the fact that the bonding between these two regions takes place by adsorption, more particularly by weak interactions of the van der Waals type; and

the operation carried out at high temperature (around 200 to 300° C.) may damage the chromophore and prevent the use of a wide range of chromophores having low decomposition temperatures.

Thus, it is apparent from the embodiments of the prior art that they have one or more of the following drawbacks that limit the performance:

limited interpenetration of the n-semiconductor region and the p-semiconductor region;

high rate of electron-hole recombination at the junction between these regions owing to the low degree of interpenetration of the various n-region/chromophore/p-region components; and

weak junction between the p-region and the n-junction owing to the weak character of the bonds participating at said junction.

The inventors therefore set themselves the objective of providing a pn-type semiconductor material which is free of the abovementioned drawbacks, especially in that there is strong interaction between the p-semiconductor region and the n-semiconductor region, and which, however, allows the short-circuit phenomena between these two regions to be limited.

These objects are achieved by the present invention, which proposes in particular a pn-type semiconductor inorganic/organic hybrid material.

### DETAILED DESCRIPTION OF THE INVENTION

Thus, the invention relates, according to a first subject matter, to a pn-semiconductor material that can be obtained by a method comprising in succession the following steps:

a step in which a substrate made of a porous oxide ceramic (which may or may not be sensitized with one or more chromophores) is functionalized by chemical grafting of one or more compounds containing at least one group that can be polymerized with one or more precursors of an electrically conducting polymer and at least one group able to be chemically grafted onto said substrate;

a step in which said substrate thus functionalized is impregnated with a solution containing said precursor(s); and

a step in which said precursor or precursors are polymerized.

Before going into more detail in the description, we propose the following definitions.

The expression “pn-semiconductor material” is understood to mean a material comprising both an n-type semiconductor region and a p-type semiconductor region. For the purpose of the invention, the n-type semiconductor region may be formed by the abovementioned substrate, in which case the p-type conducting region will be formed by the electrically conducting polymer or polymers resulting from the polymerization step. Conversely, the n-type conducting region may be formed by the electrically conducting polymer or polymers resulting from the polymerization step, in which case the p-type semiconductor region is formed by the porous ceramic substrate. It should also be pointed out that this material may be in the form of a block (or a piece) or else in the form of a coating (for example a film having a thickness of 10 nm to 100 μm).

The expression “electrically conducting polymer” is understood in general to mean a polymer having electrical conduction properties without being doped (in which case the polymer will be an intrinsically conducting polymer) or when it is doped (in which case the polymer will be an extrinsically conducting polymer), the electrical conduction being provided either with electrons (with regard to n-type conducting polymers) or by holes which correspond to “spaces” left vacant by electrons (with regard to p-type conducting polymers). Specific examples of these various types of polymers will be given later.

The expression “chemical grafting” is understood, both in the foregoing text and that which follows, as immobilization of the above-mentioned compound or compounds on the abovementioned substrate by means of a covalent, or even ionic-covalent, chemical bond, thanks to the presence on the compound or compounds, during the functionalization step, of one or more groups able to be grafted onto the substrate. It should be pointed out that this immobilization takes place both on the external surface of the substrate and also the internal surfaces of said substrate, that is to say on the surface of the pore walls of the substrate.

The expression “group able to be chemically grafted onto said substrate” is in general understood to mean groups able to react with the reactive groups present on the oxide ceramic in order to give a covalent or ionic-covalent bond. The reactive groups of the substrate may be —OH groups, these —OH groups resulting from a spontaneous hydration of the ceramic, or from the effect of ambient atmospheric moisture, or from the effect of moisture caused by creating these groups.

The expression “electrically conducting polymer precursor” is understood in general to mean monomers or possibly oligomers (assemblies of two or several tens of monomeric units), the polymerization of which results in electrically conducting polymers.

Thus, contrary to the embodiments of the prior art, the pn-semiconductor material has a junction between the p-semiconductor region and the n-semiconductor region resulting from chemical grafting.

The materials of the invention therefore have a better junction than the materials of the prior art between the surface of the oxide ceramic substrate and the polymer(s) resulting from the step of polymerizing said abovementioned precursor(s).

In addition, the materials of the invention have improved interpenetration of the polymers into the ceramic. This is due to the fact that the materials of the invention are obtained by a method involving a step of impregnating a porous oxide ceramic substrate with polymer precursors and not with polymers themselves, thereby improving the interpenetration into the porous ceramic of the infiltrating species because the precursors are smaller in size than the polymers used in the prior art.

Thus, the materials of the invention have both a better junction between the surface of the oxide ceramic substrate and the polymer(s) and better interpenetration of said polymers into the porous ceramic and therefore better interpenetration of the abovementioned n- and p-regions.

The group or groups able to be chemically grafted onto the ceramic may be chosen from the groups having the following formulae:

COOR¹ with R¹ representing a hydrogen atom, an alkyl group containing 1 to 30 carbon atoms, or a phenyl group;

COCl;

COCH₂CO—R¹ with R¹ representing a hydrogen atom, an alkyl group containing 1 to 30 carbon atoms, or a phenyl group;

PO(OH)₂, —PO(OR²) (OH) or —PO(OR²)(OR³) with R² and R³, which are identical or different, representing an alkyl group containing 1 to 30 carbon atoms, or a phenyl group;

CO(NHOH);

M(OR⁴)ₙ₋ₓ₋₁Z^{x} with x being an integer ranging from 1 to (n−1), M being a metal or a metalloid, n being an oxidation number of M, R⁴ representing a hydrogen atom, an alkyl group containing 1 to 30 carbon atoms, a phenyl group, a monovalent metal cation or a group of formula N⁺R¹₄, with R¹ representing a hydrogen atom, an alkyl group containing 1 to 30 carbon atoms, or a phenyl group, and Z represents a hydrogen atom, an alkyl group containing 1 to 30 carbon atoms, a phenyl group or a halogen atom;

SO₃M′ with M′ representing a hydrogen atom, a monovalent metal cation or a group of formula N⁺R¹₄ with R¹ representing a hydrogen atom, an alkyl group containing 1 to 30 carbon atoms, or a phenyl group;

B(OM′)₂ with M′ representing a hydrogen atom, a monovalent metal cation or a group of formula N⁺R¹₄ with R¹ representing a hydrogen atom, an alkyl group containing 1 to 30 carbon atoms, or a phenyl group;

OH;

and combinations thereof.

In the group of formula -M(OR⁴)ₙ₋ₓ₋₁Zₓ as defined above, M may represent a metal element, such as a transition element of given oxidation number n or a metalloid, such as Si, Ge or Te, of given oxidation number n, the conceivable oxidation numbers for each metal or metalloid element being known to those skilled in the art. As an example of a group according to this definition, the group having the following formula may be mentioned:

Si(OR⁴)₃₋ₓZₓ with x being an integer ranging from 1 to 3 and Z having the same definition as given above.

The chemical grafting onto the porous oxide ceramic substrate advantageously takes place by the abovementioned groups. It should be pointed out that the group or groups able to be polymerized and the abovementioned groups may be bonded directly via a single covalent bond or via an alkylene group containing 1 to 30 carbon atoms or a phenyl group.

The groups listed above forming a bridge between the ceramic substrate and the group able to be polymerized are particularly advantageous for the purpose of this invention as these groups are always electrical non-conductors.

The group or groups that can be polymerized with one or more precursors of an electrically conducting polymer may advantageously be chosen from the groups: acetylene, p-phenylene; p-phenylenevinylene, p-phenylenesulfide, pyrrole, thiophene, furan, azulene, azine, aniline, cyanophenylenevinylene and p-pyridyl vinylene.

One example of a compound that may advantageously be used in the functionalization step, especially with a titanium dioxide substrate, this compound comprising both a group able to be chemically grafted onto the substrate (this group being —COOH) and a group able to be polymerized with an electrically conducting polymer precursor (this group being a thiophene group), is the compound having the following formula:

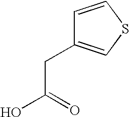

As was mentioned above, the substrate is a semiconductor porous oxide ceramic. It is understood that, depending on whether the electrically conducting polymer or polymers are n-type polymers or p-type polymers, the oxide ceramic will be chosen so as to be of the p-type or n-type, this choice being within the competence of a person skilled in the art. The oxide ceramics may be ceramics based on transition metals chosen from Ti, V, Cr, Mn, Fe, Co, Ni, Cu, Zn, Y, Zr, Nb, Mo, Ru, Rh, Pd, Ag, Cd, Hf, Ta, W, Re, Os, Ir and Pt, or based on lanthanides, such as La, Ce, Pr, Nd, Sm, Eu, Gd, Tb, Dy, Er and Yb, or based on elements of Group IIIA of the Periodic Table of Elements chosen from Al, Ga, In and Tl, or based on elements of Group IVA of the Periodic Table of the Elements chosen from Si, Ge, Sn and Pb, or based on elements of Group VIA of the Periodic Table of the Elements, chosen from Se and Te. The oxide ceramics may also be any combination of transition metals, lanthanides, elements of Group IIIA, elements of Group IVA and elements of Group VIA.

For the purpose of the present invention, the expression “porous oxide ceramic” is understood in general to mean a metallic ceramic having oxygen atoms and having generally open porosity. Suitable ceramics may be amorphous, nanocrystalline and/or mesoporous oxide ceramics.

The term “amorphous oxide ceramic” is understood in general to mean a ceramic having no crystallites or crystallites of sub-nanoscale size.

The term “nanocrystalline oxide ceramic” is understood in general to mean a ceramic having crystallites of the order of a few nanometers, for example 2 to 200 nm, in size.

Finally, the term “mesoporous oxide ceramic” is understood in general to mean a ceramic characterized by a high porosity, with pore sizes ranging from 2 to 80 nm and walls of from 5 to 30 nanometers in thickness. In general, the pores are randomly distributed with a very broad pore size distribution, within the abovementioned range. The mesoporous ceramics used according to the invention are advantageously “mesostructured” ceramics, which are in the form of organized porous networks that have an ordered spatial arrangement of mesopores. This spatial periodicity of the pores is characterized by the appearance of at least one low-angle peak in an X-ray scattering pattern, this peak being associated with a repeat distance of generally between 2 and 50 nm. The mesostructured materials are characterized by a maximized surface area for a given volume and by continuity of the solid network along at least one direction in space through the constituent walls of said material.

An example of a porous oxide ceramic that can be used according to the invention is titanium dioxide TiO₂.

A person skilled in the art may choose, from the ceramics considered in the above paragraphs, n-type ceramics (in which case the grafted conducting polymer will be a p-type polymer) and/or p-type ceramics (in which case the grafted conducting polymer will be an n-type polymer).

According to the invention, after the method has been carried out, both the surface and the interior of the porous ceramic substrate are grafted with one or more electrically conducting polymers.

Suitable polymers may be chosen from the group formed by: polyacetylene, poly(p-phenylene), poly(p-phenylenevinylene), poly(p-phenylenesulfide), polypyrrole, polythiophene, polyfuran, polyazulene, polyazine, polyaniline, polycyanophenylenevinylene and poly(para-pyridyl vinylene), and also any form of mixtures thereof.

In this list of polymers, polycyanophenylenevinylene and poly(p-pyridyl vinylene) are n-type polymers.

In this list of polymers, poly(p-phenylene), poly(p-phenylenevinylene), poly(p-phenylenesulfide), polypyrrole, polythiophene, polyfuran, polyazulene, polyazine and polyaniline are p-type polymers.

Finally, said material may further include one or more chromophores that sensitize said ceramic. It should be pointed out that, depending on the nature of the chromophore, this may be either adsorbed by or chemically grafted onto the surface and the interior of the oxide ceramic substrate.

It should be pointed out that, according to the invention, the term “chromophore” is generally understood to mean a substance able to absorb light in the IR, UV and visible range and to release electrons in turn for this absorption. Within the context of the invention, the electrons will be captured either by the oxide ceramic (if this is an n-semiconductor) or by the electrically conducting polymer(s) (if these are n-type polymers), whereas the holes left by the released electrons are captured either by the oxide ceramic (if this is a p-type semiconductor) or by the electrically conducting polymer(s) (if these are p-type polymers).

It will be understood that a given chromophore has a well-defined spectral sensitivity and that the choice of this substance must be tailored to the light source, so as to have the highest possible light absorption efficiency.

The invention also relates, according to a second subject matter, to a method of preparing a semiconductor material as defined above, comprising in succession the following steps:

a step in which a substrate made of a porous oxide ceramic (which may or may not be sensitized with one or more chromophores) is functionalized by chemical grafting of one or more compounds containing at least one group that can be polymerized with one or more precursors of an electrically conducting polymer and at least one group able to be chemically grafted onto said substrate;

a step in which said substrate thus functionalized is impregnated with a solution containing said precursor(s); and

a step in which said precursor or precursors are polymerized.

Thus, the method of the invention makes it possible, thanks to the step in which the porous oxide ceramic is functionalized by one or more of the aforementioned compounds, to improve the junction between the surface of the oxide ceramic substrate and the polymer(s) resulting from the step of polymerizing said abovementioned precursor(s).

The method of the invention involves, like certain methods of the prior art, a step of impregnating a porous oxide ceramic substrate but, unlike the prior art, the impregnation according to the invention takes place with polymer precursors and not polymers themselves. This improves the interpenetration into the porous ceramic of the infiltrating species because the size of the precursors is smaller than that of the polymers used in the prior art.

Thanks to the two abovementioned steps, the method of the invention provides both a better junction between the surface of the oxide ceramic substrate and the polymer or polymers and better interpenetration of the latter into the porous ceramic, and therefore better interpenetration of the abovementioned n- and p-regions.

As mentioned above, the method according to the invention comprises, firstly, a step in which the surface of a porous oxide ceramic substrate is functionalized by said substrate being brought into contact with one or more compounds as defined above.

For the purpose of the present invention, the expression “porous oxide ceramic” is understood to mean a ceramic as defined above. The compound or compounds comprising a group able to be polymerized with one or more precursors of an electrically conducting polymer are compounds able to be chemically grafted onto the surface of the aforementioned oxide ceramic. They are as defined above.

Groups that can be polymerized may for example be the following groups: acetylene, p-phenylene, p-phenylenevinylene, p-phenylenesulfide, pyrrole, thiophene, furan, azulene, azine, aniline, cyanophenylenevinylene and p-pyridyl vinylene. For these groups, the precursors able to be polymerized with them will be, respectively, the following monomers: acetylene, p-phenylene, p-phenylenevinylene, p-phenylenesulfide, pyrrole, thiophene, furan, azulene, azine, aniline, cyanophenylenevinylene and p-pyridyl vinylene, which will give, after polymerization, the following polymers respectively: polyacetylene, poly(p-phenylene), poly(p-phenylenevinylene), poly(p-phenylenesulfide), polypyrrole, polythiophene, polyfuran, polyazulene, polyazine, polyaniline, polycyanophenylenevinylene and poly(p-pyridyl vinylene).

The groups able to be chemically grafted onto the surface of an oxide ceramic and the groups that can be polymerized during a polymerization reaction may either be bonded directly (that is to say via a single bond) or separated by a spacer group, which may be an alkylene group containing 1 to 30 carbon atoms, or a phenylene group. The presence of such a spacer group makes it possible to adjust the distance between one or more chromophores, if these are present.

As mentioned above, a ceramic surface is functionalized by compounds as defined above, said compounds being chemically grafted onto said surface.

To obtain such a functionalization, various techniques may be envisaged, in particular liquid processing techniques, that is to say those in which the abovementioned substrate is impregnated with a solution containing the compound or compounds as defined above.

Thus, the functionalization by chemical grafting of the surface and of the interior of the porous oxide ceramic may be carried out by one of the following techniques:

dip coating;

spin coating;

laminar-flow coating;

spray coating;

soak coating;

roll-to-roll coating;

brush coating; and

screen printing.

Advantageously, these various techniques must be employed for a suitable time, so as to allow optimum contact between the porous oxide ceramic substrate and the solution containing the compound(s) able to be grafted, so that the substrate is impregnated both on its surface and on its interior and so that the compounds can react and be chemically bonded to the surface and to the interior of said substrate.

It should be pointed out that the solution may also include one or more chromophores, in which case the functionalization step will be accompanied by sensitization of the oxide ceramic substrate by said chromophore(s).

As an alternative, the method of the invention may also include a step in which said substrate is impregnated, before or after the functionalization step, with a solution containing one or more chromophores so as to sensitize said substrate.

The chromophore or chromophores that may be considered are the same as those mentioned above.

One particularly advantageous compound used in the functionalization step is the compound having the following formula:

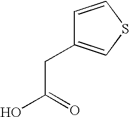

This compound comprises a —CO₂H group able to be chemically grafted onto the surface of an oxide ceramic substrate, such as TiO₂, and a thiophene group able to be polymerized with one or more electrically conducting polymer precursors, in particular with an alkylthiophene precursor.

After this functionalization step, the method of the invention may include a treatment step intended to remove the residues of the grafting reaction and also the unreacted species.

It should be pointed out that the grafting or adsorption of chromophores, may, depending on the case, be carried out by the same means as the functionalization by the compounds as defined above, or it may even be carried out simultaneously with said functionalization.

Once the functionalization step has been completed, the method of the invention provides a step in which the substrate thus functionalized is impregnated with one or more precursors as defined above.

Specifically, this step consists in general in impregnating the substrate thus functionalized with an organic solution containing said precursor(s).

The impregnation with one or more electrically conducting polymer precursors takes place by liquid processing, more precisely by one of the abovementioned techniques:

dip coating;

spin coating;

laminar-flow coating;

spray coating;

soak coating;

roll-to-roll coating;

brush coating; and

screen printing.

These techniques must be carried out for a suitable time so as to impregnate both the surface of the oxide ceramic substrate and its pores.

Once the impregnation step has been completed, it is then possible to start the polymerization step. This step consists in growing, by polymerization of the precursors, polymer chains starting from the polymerizable groups present on the compound or compounds of the functionalization step.

This polymerization step may start by the addition, into the abovementioned solution, of a polymerization initiator when the envisaged polymerization is a chemical polymerization.

The term “polymerization initiator” is understood to mean a reactant that can initiate the polymerization reaction between the compounds grafted during the functionalization step and the abovementioned precursor(s). Specifically, this initiator will create reactive centers, from which the polymerization reaction propagates. The choice of initiator will be easily made by those skilled in the art according to the polymer to be synthesized. In particular, this initiator may be an oxidizing agent (for example, iron trichloride FeCl₃) in order to polymerize compounds of the polythiophene family by chemical oxidation.

It is also conceivable according to the invention, for the precursors of the invention to undergo electrochemical polymerization. In this case, current is made to flow through the substrate impregnated with the solution containing said precursor(s), said current initiating the polymerization of said precursor(s).

Precursors capable of being polymerized by electrochemical polymerization are for example thiophene, pyrrole and analogs thereof.

Once the polymerization step has been completed, the method of the invention may include a treatment step intended to remove the solvent or solvents present in the impregnation solution, the reaction residues and the unreacted precursors.

The method according to the invention has many advantages:

it allows good interpenetration between a porous oxide ceramic region and the electrically conducting polymers grafted onto the surface of this region; and

it employs simple techniques that can be carried out at room temperature.

The semiconductor materials of the invention may be used in various devices requiring the presence of a semiconductor material, such as electrochemical devices, photoelectrochemical devices and catalytic devices, and in particular in photovoltaic cells or in light-emitting diodes.

Thus, the subject of the present invention is also a photovoltaic cell comprising:

a current-collecting first electrode (called a “working electrode”);

a second electrode (called a “counterelectrode”); and

a semiconductor region consisting of the semiconductor material as defined above, said region being placed between said first electrode and said second electrode.

The first electrode, or working electrode, comprises a conducting portion, for example in the form of a layer of fluorine-doped tin oxide, this portion possibly being deposited on a support.

It should be pointed out that the term “support” is understood in general, for the purpose of the invention, to mean any organic or inorganic substrate, characterized by a transparency of at least 50% in the solar spectrum. This support may for example be made of transparent glass.

It should be noted that the above-mentioned conducting portion will be in contact with the abovementioned semiconductor region, either directly or via a dense titanium dioxide layer, the latter making it possible to prevent direct contact between the working electrode and the semiconductor region and consequently preventing a short circuit in the photovoltaic cell.

It is also pointed out that the layer based on an electrically conducting polymer may be interposed between said semiconductor region and the second electrode (the counterelectrode), so as to avoid a short circuit in the photovoltaic cell.

In general, the second electrode (or counterelectrode) is in the form of a metal layer, for example a metal layer based on gold and/or nickel.

The photovoltaic cells designed on the basis of the pn-semiconductor inorganic/organic hybrid material of the invention has the following advantages:

the fact of grafting electrically conducting polymers, via compounds as defined above, onto and into the porous oxide ceramic promotes charge transfer during electron-hole association between the ceramic, the conducting polymers and optionally the chromophore(s); and

the fact of using a semiconductor material according to the invention exhibiting excellent interpenetration of the n-regions and p-regions means that said photoactive electrode is effective over its entire thickness and thus provides a configuration favorable for improving the solar efficiency of solid-state, optionally dye-based, photovoltaic cells.

FIG. 1 shows a photovoltaic cell according to the present invention, denoted by the overall reference 1.

The cell 1 comprises a transparent glass support 3 coated on one face 5 with a transparent conducting layer 7, this layer possibly being based on fluorine-doped tin oxide. The support coated with the transparent conducting layer acts as current-collecting electrode (or the first electrode in the terminology employed above).

A dense titanium dioxide layer 9 is deposited on the transparent conducting layer 7. Placed on this dense layer is a layer 11 of semiconductor material, said semiconductor material corresponding to the pn-semiconductor inorganic/organic hybrid material of the invention. Deposited on this layer 11 of semiconductor material is a layer 13 of conducting polymer, on which a metal layer 15, for example a layer based on gold and nickel, is deposited. The layer 13 of conducting polymer, sandwiched between the layer 11 of semiconductor material and the metal layer 15, makes it possible to limit short-circuiting. The metal layer 15 acts as counterelectrode (or second electrode in the terminology employed above).

FIG. 2 shows an enlarged portion of the layer 11 of semiconductor material and more precisely the interface between the surface of the porous oxide ceramic substrate and the electrically conducting polymer and a chromophore.

In this figure, the reference 17 denotes a surface of the wall of a pore of the porous oxide ceramic. An electrically conducting polymer 19 is grafted onto this surface via a compound 21, as defined above, containing a group that allows chemical grafting onto the surface 17 of the wall of a pore of the porous oxide ceramic. Near this electrically conducting polymer 19, the surface 17 is sensitized by a chromophore 23 (adsorbed or grafted onto said surface). When a light ray reaches the chromophore (said light ray being represented by an arrow hν), the light energy in photon form that it transports is absorbed by the chromophore. The latter releases an electron e⁻ which, in this situation, is captured directly by the porous oxide ceramic, while the hole shown by the + symbol, created concomitantly with the electron, is captured by the conducting polymer. Thus, the electron-hole pair dissociates without recombining, therefore creating an electric current within the material.

The photovoltaic cells of the present invention may be produced by the following steps:

a deposition step, in which an oxide ceramic film is deposited on a support optionally coated with a transparent conducting layer, it being possible for said deposition to be carried out by vacuum techniques or by wet processing techniques, as described above, these two types of methods being within the competence of those skilled in the art;

the method for producing the semiconductor material as defined above is implemented so as to obtain said semiconductor material from the abovementioned oxide ceramic film;

optionally, a step of depositing, on the layer of conducting material, a layer of electrically conducting polymer, preferably identical to the constituent polymer of the pn-semiconductor inorganic/organic hybrid material of the invention, said layer being deposited by wet processing techniques, described above, within the competence of a person skilled in the art; and

a deposition step in which a metal layer as defined above is deposited on the layer of semiconductor material or, where appropriate, on the layer of electrically conducting polymer.

The present invention will now be described in relation to an exemplary embodiment.

### BRIEF DESCRIPTION OF THE DRAWINGS AND OF THE SPECTRA

FIG. 1 corresponds to a sectional view of a photovoltaic cell of the invention, already described.

FIG. 2 corresponds to an enlargement of a portion of the cell shown in FIG. 1, this portion being described above.

FIG. 3 shows the transmission spectrum (shown by the black curve) of a photovoltaic cell without a counterelectrode, produced according to the embodiment proposed below, and, by way of comparison, the solar emission spectrum (shown by the gray curve).

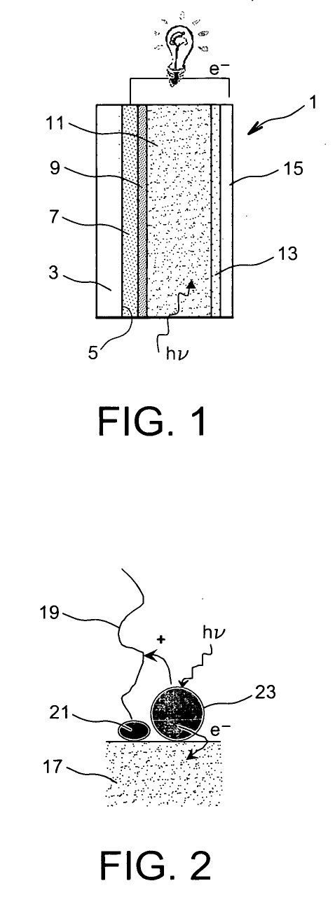

The invention will now be described with reference to the example below.

### DETAILED DESCRIPTION OF PARTICULAR EMBODIMENTS

### Example

### Method for Forming a pn-Semiconductor Inorganic/Organic Hybrid Material for the Production of a Photovoltaic Cell

A glass substrate measuring 2×5 cm², coated with a transparent conducting layer based on SnO₂:F (manufactured by the Japanese company Asahi Glass Corporation) having a surface resistance of the order of 10 ohms². and partially coated with a thin layer of dense TiO₂ deposited by hot spraying, was firstly cleaned using a detergent, then thoroughly rinsed with water, and dried with ethanol.

The layer of pn-semiconductor inorganic/organic hybrid material of the invention was firstly prepared by depositing, on the dense TiO₂ layer, a porous TiO₂ layer by screen printing using the paste sold under the name Ti-Nanoxide HT by the Swiss company Solaronix. The whole assembly was then densified at 450° C. for 15 minutes. The layer of TiO₂ porous oxide ceramic obtained had a thickness of 3 μm. It constituted the n-type semiconductor material of the pn-semiconductor inorganic/organic hybrid material.

The compound containing a thiophene unit and a carboxylic group, for chemically grafting onto the surface of the wall of a pore of the porous oxide ceramic, selected was 3-thiopheneacetic acid (sold by Aldrich under the reference 22,063-9), having the following formula:

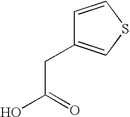

The chromophore chosen was cis-bis(isothiocyanato)bis(2,2′-bipyridyl-4,4′-dicarboxylato)ruthenium(II)bis-tetrabutylammonium) sold under the name Ruthenium 535 bis-TBA by the Swiss company Solaronix.

The compound and the chromophore were dissolved in equimolar proportions in an ethanol-based solution.

The TiO₂ porous oxide ceramic was then immersed in the solution containing the compound and the chromophore for 24 hours. Thus, the compound and the chromophore were grafted onto the surface of the wall of a pore of the TiO₂ porous oxide ceramic thanks to their complexing carboxylic groups. The porous oxide ceramic thus functionalized was then rinsed with ethanol.

After grafting the compound and the chromophore, the electrically conducting polymer constituting the p-semiconductor material of the pn-semiconductor inorganic/organic hybrid material was produced in the following manner: the oxide layer thus functionalized was immersed in a 0.1M alkylthiophene solution in chloroform. A 0.3M iron chloride (FeCl₃) solution was then introduced so as to initiate the polymerization. After 12 h at room temperature, the substrate was rinsed with chloroform and then with ethanol. Finally, the substrate was carefully rinsed with chloroform so as to extract the ungrafted polymer.

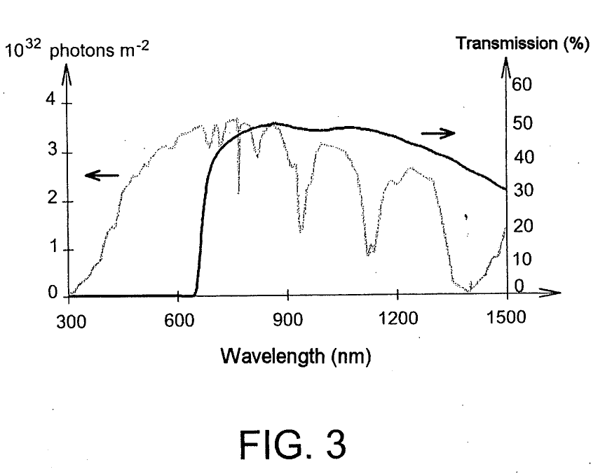

A conducting polymer layer was then deposited on the layer of pn-semiconductor inorganic/organic hybrid material by spin coating using a 5 wt % polyalkylthiophene solution in chloroform. FIG. 3 shows the transmission spectrum of the stack thus formed.

A gold counterelectrode was deposited on the conducting polymer layer by vacuum evaporation.

On illuminating the photovoltaic cell thus produced, an electric current was observed between the electrode and the counterelectrode. This shows that pn-semiconductor inorganic/organic hybrid material in layer form absorbs the constituent photons from the light, creates an electron and a hole (referred to as an electron-hole pair), dissociates said pair at the pn junction, creates a potential difference at the pn junction and thus generates an electric current between the electrode and the counterelectrode.

### REFERENCES CITED

[1] WO 93/19479;
[2] EP 1 176 646;
[3] EP 0 917 208;
[4] WO 93/20569.

1. A pn-semiconductor material that can be obtained by a method comprising in succession the following steps:
a step in which a substrate made of a porous oxide ceramic is functionalized by chemical grafting of one or more compounds containing at least one group that can be polymerized with one or more precursors of an electrically conducting polymer and at least one group able to be chemically grafted onto said substrate;
a step in which said substrate thus functionalized is impregnated with a solution containing said precursor(s); and
a step in which said precursor or precursors are polymerized.

2. The semiconductor material as claimed in claim 1, in which the porous oxide ceramic is chosen from ceramics based on transition metals chosen from Ti, V, Cr, Mn, Fe, Co, Ni, Cu, Zn, Y, Zr, Nb, Mo, Ru, Rh, Pd, Ag, Cd, Hf, Ta, W, Re, Os, Ir and Pt, or based on lanthanides, such as La, Ce, Pr, Nd, Sm, Eu, Gd, Th, Dy, Er and Yb, or based on elements of Group IIIA of the Periodic Table of Elements chosen from Al, Ga, In and Tl, or based on elements of Group IVA of the Periodic Table of the Elements chosen from Si, Ge, Sn and Pb, or based on elements of Group VIA of the Periodic Table of the Elements, chosen from Se and Te, and combinations thereof.

3. The semiconductor material as claimed in claim 1, in which the porous oxide ceramic is a mesoporous ceramic.

4. The semiconductor material as claimed in claim 3, in which the mesoporous ceramic is mesostructured.

5. The semiconductor material as claimed in claim 1, in which the ceramic is titanium dioxide TiO₂.

6. The semiconductor material as claimed in claim 1, in which the group or groups able to be chemically grafted onto the ceramic are chosen from the groups having the following formulae:
COOR¹ with R¹ representing a hydrogen atom, an alkyl group containing 1 to 30 carbon atoms, or a phenyl group;
COCl;
COCH₂CO—R¹ with R¹ representing a hydrogen atom, an alkyl group containing 1 to 30 carbon atoms, or a phenyl group;
PO(OH)₂, —PO(OR²)(OH) or —PO(OR²)(OR³) with R² and R³, which are identical or different, representing an alkyl group containing 1 to 30 carbon atoms, or a phenyl group;
CO(NHOH);
M(OR⁴)ₙ₋ₓ₋₁Zₓ with x being an integer ranging from 1 to (n−1), M being a metal or a metalloid, n being an oxidation number of M, R⁴ representing a hydrogen atom, an alkyl group containing 1 to 30 carbon atoms, a phenyl group, a monovalent metal cation or a group of formula N⁺R¹₄, with R¹ representing a hydrogen atom, an alkyl group containing 1 to 30 carbon atoms, or a phenyl group, and Z represents a hydrogen atom, an alkyl group containing 1 to 30 carbon atoms, a phenyl group or a halogen atom;
SO₃M′ with M′ representing a hydrogen atom, a monovalent metal cation or a group of formula N⁺R¹₄ with R¹ representing a hydrogen atom, an alkyl group containing 1 to 30 carbon atoms, or a phenyl group;
B(OM′)₂ with M′ representing a hydrogen atom, a monovalent metal cation or a group of formula N⁺R¹₄ with R¹ representing a hydrogen atom, an alkyl group containing 1 to 30 carbon atoms, or a phenyl group;
OH;
and combinations thereof.

7. The semiconductor material as claimed in claim 1, in which the group or groups that can be polymerized with one or more precursors of an electrically conducting polymer are chosen from the groups: acetylene, p-phenylene, p-phenylenevinylene, p-phenylenesulfide, pyrrole, thiophene, furan, azulene, azine, aniline, cyanophenylenevinylene and p-pyridyl vinylene.

8. The semiconductor material as claimed in claim 1, which further includes one or more chromophores that sensitize said ceramic.

9. The semiconductor material as claimed in claim 1, in which:
the porous oxide ceramic substrate is a TiO₂ substrate;
the compound used in the functionalization step satisfies the following formula: 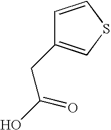
the precursor used in the impregnation step is an alkylthiophene.

10. A method of preparing a semiconductor material as defined in claim 1, comprising in succession the following steps:
a step in which a substrate made of a porous oxide ceramic is functionalized by chemical grafting of one or more compounds containing at least one group that can be polymerized with one or more precursors of an electrically conducting polymer and at least one group able to be chemically grafted onto said substrate;
a step in which said substrate thus functionalized is impregnated with a solution containing said precursor(s); and
a step in which said precursor or precursors are polymerized.

11. A photovoltaic cell comprising:
a current-collecting first electrode;
a second electrode; and
a semiconducting region consisting of a material as defined in claim 1, said region being placed between said first electrode and said second electrode.
